(19) United States
(12) Patent Application Publication
(10) Pub. No.: US 2026/0121382 A1
(43) Pub. Date: Apr. 30, 2026

(54) EDGE-EMITTING SEMICONDUCTOR BROAD AREA LASER

(71) Applicant: NLIGHT, INC., Camas, WA (US)

(72) Inventor: Manoj Kanskar, Portland, OR (US)

(21) Appl. No.: 19/098,581

(22) Filed: Apr. 2, 2025

Related U.S. Application Data
(60) Provisional application No. 63/573,597, filed on Apr. 3, 2024.

(51) Int. Cl. H01S 5/20; H01S 5/12

(52) U.S. Cl. CPC H01S 5/2036; H01S 5/12

(57) ABSTRACT

An edge-emitting semiconductor broad area laser includes a chip, an emitter disposed on the chip, a grating structure disposed on the emitter, and a metal layer disposed on the grating structure. When operational, the emitter emits laser light from the first end thereof. The grating structure includes a plurality of grooves that exhibit progressively larger radii of curvature between the first end and the second end.

### CROSS-REFERENCE TO RELATED APPLICATION(S)

This United States patent application relies on and claims priority to U.S. Provisional Patent Application Ser. No. 63/573,597, filed on Apr. 3, 2024, the entire contents of which are incorporated herein by reference.

### FIELD OF THE INVENTION

The present invention encompasses, inter alia, the construction of a semiconductor broad area laser. More specifically, the present invention encompasses a single mode broad area laser.

### DESCRIPTION OF THE RELATED ART

Semiconductor broad area lasers are known in the art. Semiconductor broad area lasers commonly are referred to as “BALs.”

Edge-emitting, high power BALs are limited in their power (i.e., output intensity) due to a phenomenon referred to as “multi-mode operation.” Edge-emitting, high power BALs also are limited in their power due to filamentation formation due to gain-index coupling. In particular, the output beam of a BAL is multimodal and diffraction limited (e.g., by 10 times or more).

Single mode lasers based on ridge waveguide architecture (e.g., Slab-Coupled Optical Waveguide Lasers (“SCOWL”) and Ridge Waveguide (“RWG”)) are limited to a few watts of output power due to facet power loading, which can lead to catastrophic optical mirror damage (“COMD”) when operated at higher output power.

Single mode lasers based on ridge waveguide architecture also are not efficient, because the series resistance is larger (e.g., by more than 5×) when compared to BALs due to the very narrow device geometry used for single mode operation.

Other deficiencies are known to exist in BALs that limit the operational power of these devices.

In the prior art, various constructions have been employed in BALs in an attempt to improve output performance while avoiding or minimizing multi-modal operation as identified hereinabove and as discussed in greater detail hereinbelow.

### SUMMARY OF THE INVENTION

The present invention seeks to address one or more deficiencies in the prior art.

Specifically, the present invention provides for an edge-emitting semiconductor broad area laser. The edge-emitting semiconductor broad area laser includes a chip, an emitter disposed on the chip, a grating structure disposed on the emitter, and a metal layer disposed on the grating structure. When operational, the emitter emits laser light from the first end thereof. The grating structure includes a plurality of grooves that exhibit progressively larger radii of curvature between the first end and the second end.

In one contemplated embodiment, the edge-emitting semiconductor broad area laser is constructed such that the first end includes a partially reflective surface and the second end includes a highly reflective surface.

Alternatively, the first end may be provided with a highly reflective surface while the second end has a partially reflective surface.

It is contemplated that the edge-emitting semiconductor broad area laser may be fashioned such that the chip includes a first end, a second end, a first side, and a second side, the chip defines a chip length between the first end and the second end, the chip defines a chip width between the first side and the second side, the grating structure defines a grating structure length between the first end and the second end, the grating structure defines a grating width between the first side and the second side, and the grating structure width is less than or equal to the chip width.

It is also contemplated that the grating width may be less than the chip width.

Similarly, the edge-emitting semiconductor broad area laser may be constructed such that the emitter defines an emitter length between the first end and the second end, the emitter defines an emitter width between the first side and the second side, and the emitter width is less than or equal to the grating structure width.

It is also contemplated that the emitter width is less than the grating structure width.

In a contemplated embodiment of the present invention, the edge-emitting semiconductor broad area laser includes a grating structure that has a semiconductor layer combined with the metal layer. The interface between the semiconductor layer and the metal layer define peaks and valleys that establish the plurality of grooves.

In another contemplated embodiment of the edge-emitting semiconductor broad area laser, the grating structure includes a semiconductor layer, a dielectric layer, and the metal layer. Here, the dielectric layer defines peaks that establish the plurality of grooves.

In yet another contemplated embodiment, the edge-emitting semiconductor broad area laser includes a grating structure that combines a semiconductor layer, a dielectric layer, and the metal layer. Here, the semiconductor layer defines peaks that establish the plurality of grooves and the dielectric layer fills the valleys.

Still further advantages and features of the present invention will be made apparent by the discussion presented herein.

### BRIEF DESCRIPTION OF THE DRAWINGS

The present invention will now be described in connection with the drawings appended hereto, in which:

FIG. 1 is a perspective, graphical representation of one type of conventional BAL that includes an etched region at one end of the laser emitter;

FIG. 2 is a graphical, top view of a first embodiment of a single mode BAL according to the present invention;

FIG. 3 is a graphical, top view of a second embodiment of a single mode BAL according to the present invention;

FIG. 4 is a graphical, top view of a third embodiment of a single mode BAL according to the present invention;

FIG. 5 is a graphical, top view of a fourth embodiment of a single mode BAL according to the present invention;

FIG. 6 is a graphical, cross-sectional side view of a first contemplated construction for a grating structure incorporated into the single mode BALs illustrated in FIGS. 2-5;

FIG. 7 is a graphical, cross-sectional side view of a second contemplated construction for a grating structure incorporated into the single mode BALs illustrated in FIGS. 2-5;

FIG. 8 is a graphical, cross-sectional side view of a third contemplated construction for a grating structure incorporated into the single mode BALs illustrated in FIGS. 2-5;

FIG. 9 is a graphical, top view of the single mode BALs illustrated in FIGS. 2-5, depicting a first geometrical construct for the grating structure incorporated therein;

FIG. 10 is a graphical, top view of the single mode BALs illustrated in FIGS. 2-5, depicting a second geometrical construct for the grating structure incorporated therein; and

FIG. 11 is a graphical, top view of the single mode BALs illustrated in FIGS. 2-5, depicting a third geometrical construct for the grating structure incorporated therein.

### DETAILED DESCRIPTION OF EMBODIMENT(S) OF THE INVENTION

The present invention will now be described in connection with several examples and embodiments. The present invention should not be understood to be limited solely to the examples and embodiments discussed. To the contrary, the discussion of selected examples and embodiments is intended to underscore the breadth and scope of the present invention, without limitation. As should be apparent to those skilled in the art, variations and equivalents of the described examples and embodiments may be employed without departing from the scope of the present invention.

In addition, aspects of the present invention will be discussed in connection with specific materials and/or components. Those materials and/or components are not intended to limit the scope of the present invention. As should be apparent to those skilled in the art, alternative materials and/or components may be employed without departing from the scope of the present invention.

In the illustrations appended hereto, for convenience and brevity, the same reference numbers are used to refer to like features in the various examples and embodiments of the present invention. The use of the same reference numbers for the same or similar structures and features is not intended to convey that each element with the same reference number is identical to all other elements with the same reference number. To the contrary, the elements may vary from one embodiment to another without departing from the scope of the present invention.

Still further, in the discussion that follows, the terms “first,” “second,” “third,” etc., may be used to refer to like elements. These terms are employed to distinguish like elements from similar examples of the same elements. For example, one fastener may be designated as a “first” fastener to differentiate that fastener from another fastener, which may be designated as a “second fastener.” The terms “first,” “second,” “third,” are not intended to convey any particular hierarchy between the elements so designated.

It is noted that the use of “first,” “second,” and “third,” etc., is intended to follow common grammatical convention. As such, while a component may be designated as “first” in one instance, that same component may be referred to as “second, “third,” etc., in a separate instance. The use of “first,” “second,” and “third,” etc., therefore, is not intended to limit the present invention.

As noted above, to minimize deficiencies associated with the multi-modal operation of conventional BALs, one solution proposed by the prior art is to incorporate an etched region at one end of the semiconductor laser emitter.

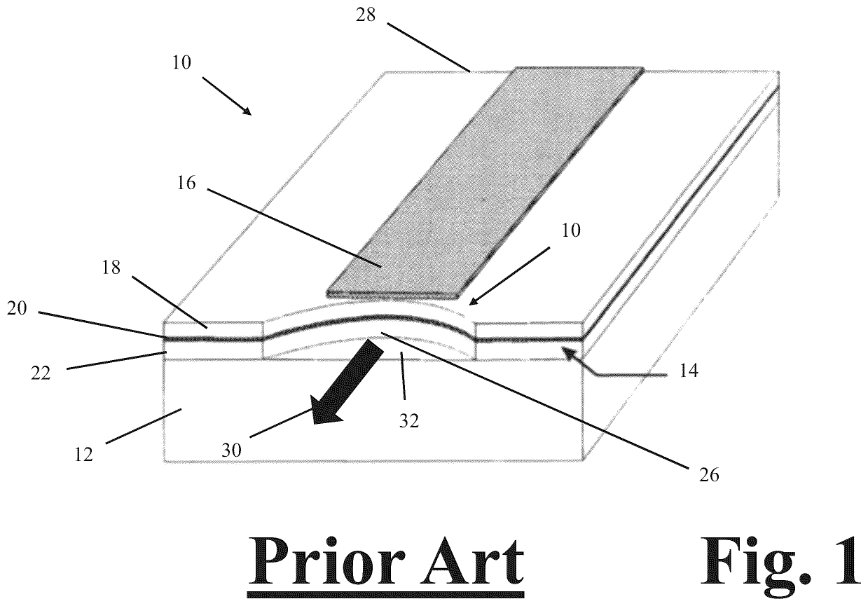

FIG. 1 illustrates this solution.

In particular, FIG. 1 is a graphical, perspective illustration of a BAL 10 known in the prior art.

The conventional BAL 10 includes a chip 12, an active layer 14, and a metal layer 16. The active layer 14 includes a P-waveguide layer 18, a quantum well gain medium 20, and an N-waveguide layer 22. The construction and operation of the active layer 14 is known to those skilled in the art and, therefore, is not discussed in greater detail herein. The metal layer 16 disposed atop the active layer 14.

The BAL 10 is provided with a partially reflective (“PR”) surface 26 and a highly reflective (“HR”) surface 28. When a voltage/current is applied to the metal layer 16, the active layer produces laser light 30 (also referred to as an output beam 30), which is emitted through the partially reflective surface 26.

As noted above, the output beam 30 of the BAL 10 is multimode and, as should be understood by those skilled in the art, is diffraction limited (by more than 10 times (10×)).

As noted above, single mode lasers that are based on ridge waveguide architecture (e.g., SCOWL, RWG) are limited to a few watts of output power due to facet power loading, which can lead to catastrophic optical mirror damage (“COMD”) when operated at higher output power. As also noted above, single mode lasers also are not particularly efficient, because the series resistance is larger (i.e., by more than 5 times (5×)) as compared to BALs due to very narrow device geometry used for single mode operation.

As should be apparent to those skilled in the art, unstable resonators (“UR”) can achieve high power with good spatial coherence (e.g., good beam quality) in non-diode lasers such as gas lasers and solid-state crystal lasers, where the geometry makes efficient use of the gain volume. As is also known, general unstable resonator cavities are based on curved mirrors which are cylindrical in the case of semiconductor slab waveguides. Etching the facets of semiconductor lasers has been used to form unstable resonators in semiconductor lasers with comparable reflectivities with cleaved mirrors and high output power.

An example of an etched facet 32 is illustrated in the conventional BAL 10 shown in FIG. 1.

The UR cavity has been formed by deep etching the front facet (partially reflective surface 26) or the back facet (highly reflective surface 28) of an edge-emitting semiconductor laser so that the etch depth goes through the entire transverse structure of the semiconductor laser (e.g., the active layer 14). While theoretically effective, such etched facets 32, in actual practice, leave defects which are prone to facet degradation leading to reliability concerns at high powers. Moreover, such deep etched structures often leave many etch-artifacts which lead to diffraction loss and degradation in performance. This is especially true for semiconductor lasers containing AlGaAs alloys, because these alloys are prone to COMD when reactively etched surfaces are formed.

The present invention avoids the use of etched facets 32. For the present invention, the solution is to employ curved gratings in an unstable resonator configuration.

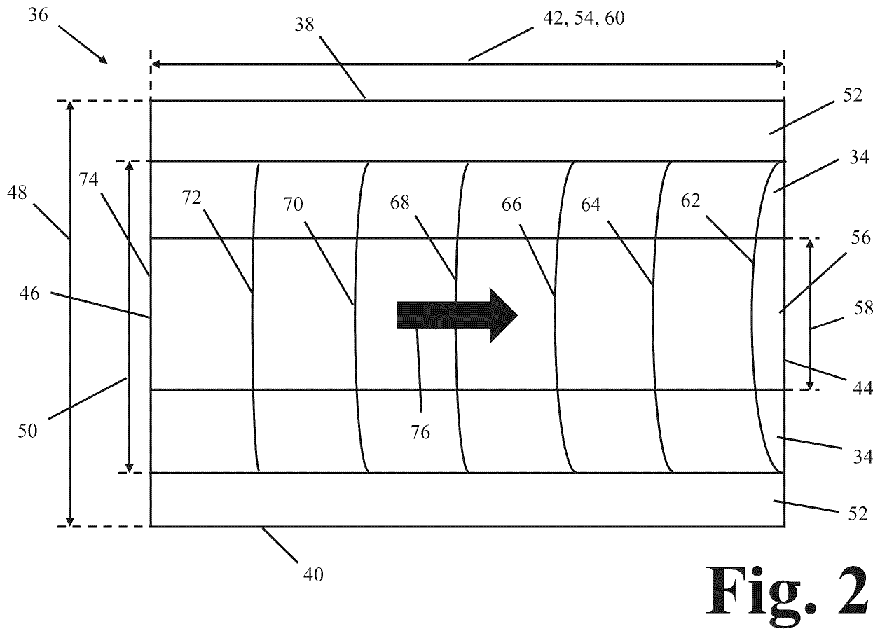

Various embodiments of this construction are discussed in connection with FIGS. 2-10, discussed hereinbelow.

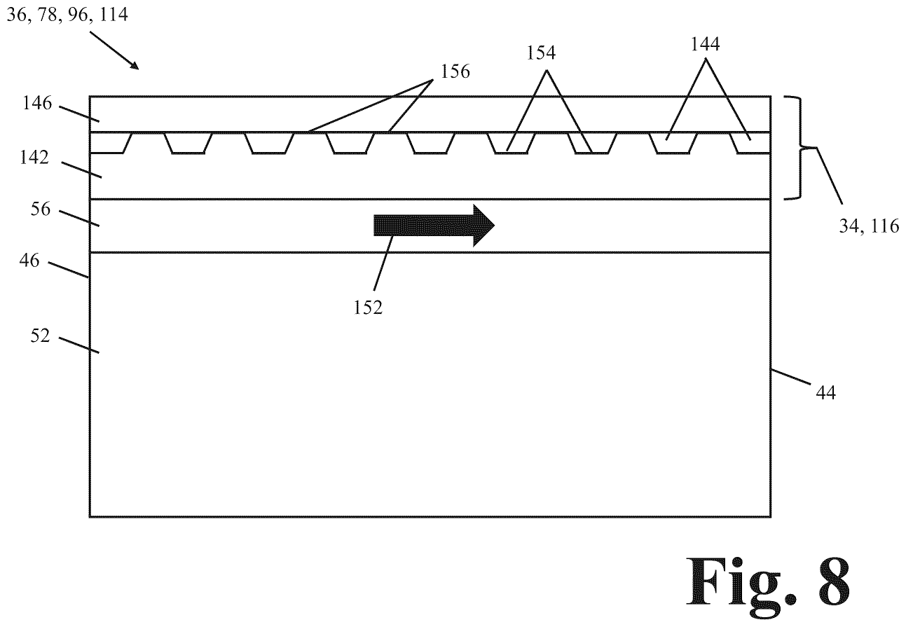

As illustrated in FIGS. 2-7, to produce the device of the present invention, which is referred to as a Single Mode Broad Area Laser (“SiMBAL”), a diffraction grating (otherwise referred to as a grating structure) 34 is provided above and adjacent to the active layer 14. A more detailed discussion of non-limiting aspects of the grating structure 34 is provided in connection with FIGS. 8-10, below.

FIG. 2 illustrates a first contemplated embodiment for a SiMBAL 36 according to the present invention. Specifically, FIG. 2 is a top, graphical illustration thereof.

The SiMBAL 36 includes a first side 38 and a second side 40. The first side 38 and the second side extend along a longitudinal direction of the SiMBAL 36, as identified by the chip length 42.

The SiMBAL 36 also includes a first end 44 and a second end 46. The first end 44 and the second end 46 extend across the chip width 48 of the SiMBAL 36. The chip width 48 is the width of the semiconductor chip (i.e., the chip), as should be apparent to those skilled in the art.

In this embodiment, the first end 44 is the partially reflective (PR) end and the second end 46 is the highly reflective (HR) end.

FIG. 2 also illustrates that the grating structure 34 defines a grating width 50. Here, the grating width 50 is less than or equal to the chip width 48, with the chip being identified as 52. As illustrated, in this embodiment, the grating width 50 is less than the chip width 48. As also illustrated, the length of the grating structure 34, referred to as the grating length 54, is equal to the chip length 42.

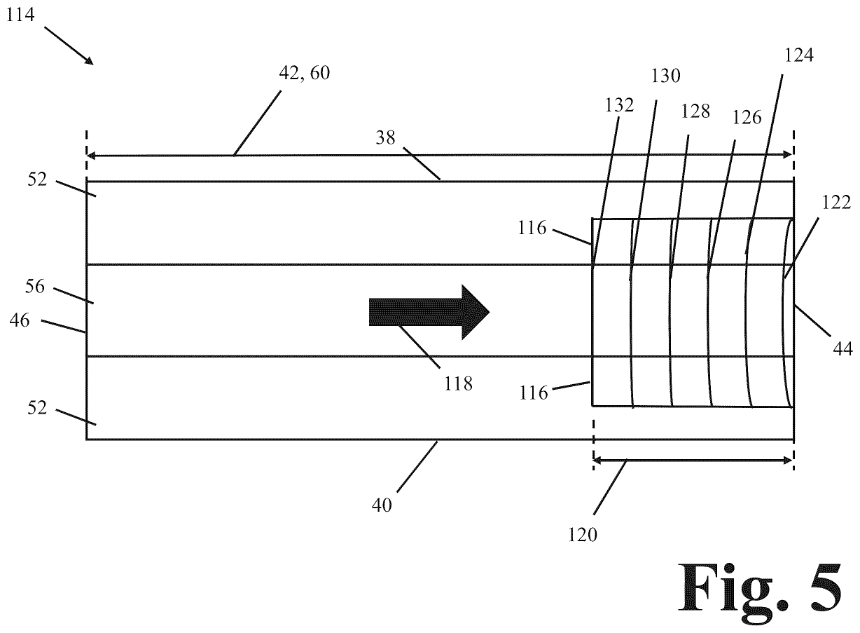

As discussed in connection with FIG. 5, for example, the grating length 54 may be less than the chip length 42 without departing from the scope of the present invention.

The SiMBAL 36 also incorporates an emitter 56 having an emitter width 58. The emitter width 58 is less than or equal to the grating width 50. In this embodiment, the emitter width 58 is less than the grating width 50, as illustrated. The emitter length 60 is equal to the chip length 42 and to the grating length 54.

It is noted that the SiMBAL 36 includes a metal layer that is disposed thereon such that the metal layer shares the same dimensions as the emitter 56. This is consistent with the illustration of the BAL 10 in FIG. 1.

The grating structure 34 incorporates a plurality of grooves, which are identified as a first groove 62, a second groove 64, a third groove 66, a fourth groove 68, a fifth groove 70, a sixth groove 72, and a seventh groove 74 in the embodiment of the SiMBAL 36 shown in FIG. 2. It is noted that the grooves 62, 64, 66, 68, 70, 72, 74 are merely a simplified representation of the multitude of grooves that may be incorporated into the grating structure 34.

The grooves 62, 64, 66, 68, 70, 72, 74 differ from one another in that the individual radius of curvature for each of the grooves 62, 64, 66, 68, 70, 72, 74 increases as one progresses from the first end 44 of the emitter 56 to the second end 46 of the emitter 56. Moreover, for the seventh groove 74, which is adjacent to the second end 46 of the emitter 56, the radius of curvature is infinite, which means that the seventh groove 74 presents itself as a straight line.

Details concerning the mathematics underlying the radii of curvature of the grooves 62, 64, 66, 68, 70, 72, 74, are provided in connection with the discussion accompanying FIGS. 8-10.

It is noted that the arcs defining the grooves 62, 64, 66, 68, 70, 72, 74 may be defined by curved lines that are part of circles, ellipses, and the like. The progressively changing radii of curvature of the grooves 62, 64, 66, 68, 70, 72, 74 reduces the generation of undesirable modes when the SiMBAL 36 generates laser light 76 that is emitted from the first end 44 of the SiMBAL 36. The arrow 76 indicates the direction of emission of the laser light 76 from the SiMBAL 36.

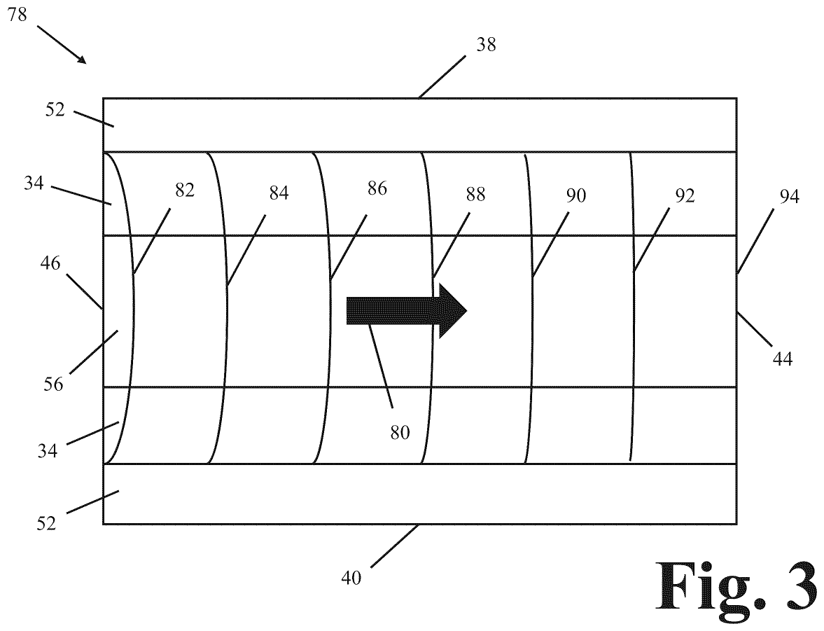

FIG. 3 is a graphical, top view of a second embodiment of a SiMBAL 78 according to the present invention.

The SiMBAL 78 shares many of the same features of the SiMBAL 36. To facilitate the discussion of the SiMBAL 78, the same reference numbers are used to refer to the same and/or similar structures described in connection with the SiMBAL 36.

SiMBAL 78 includes a chip 52, a grating structure 34, and an emitter 56. As with the SiMBAL 36, the SiMBAL 78 includes a metal layer (not shown) that is co-extensive with the footprint of the emitter 56.

The SiMBAL 78 has a first side 38 and a second side 40. As with the prior embodiment, the SiMBAL 78 has a first end 44 and a second end 46. The first end 44 is the partially reflective (PR) end. And, like the SiMBAL 36, the second end 46 is the highly reflective (HR) end.

When the emitter 56 is energized, the emitter 56 generates laser light 80 that travels in the direction of the arrow 80 to exit from the emitter 56 through the first end 44.

The SiMBAL 78 also includes a plurality of grooves 82, 84, 86, 88, 90, 92, 94. This embodiment shares the same characteristic of the prior embodiment illustrated in FIG. 2 in that the first groove 82, the second groove 84, the third groove 86, the fourth groove 88, the fifth groove 90, the sixth groove 92, and the seventh groove 94 possess different radii of curvature. As before, the radii of curvature for the grooves 82, 84, 86, 88, 90, 92, 94 increases from the first groove 82 to the seventh groove 94. And, as with the SiMBAL 36, the radius of curvature of the seventh groove 94 is contemplated to be infinite.

The SiMBAL 78 differs from the SiMBAL 36 in that the curvature of the grooves 82, 84, 86, 88, 90, 92, 94 faces the opposite direction to the grooves 62, 64, 66, 68, 70, 72, 74 in the SiMBAL 36.

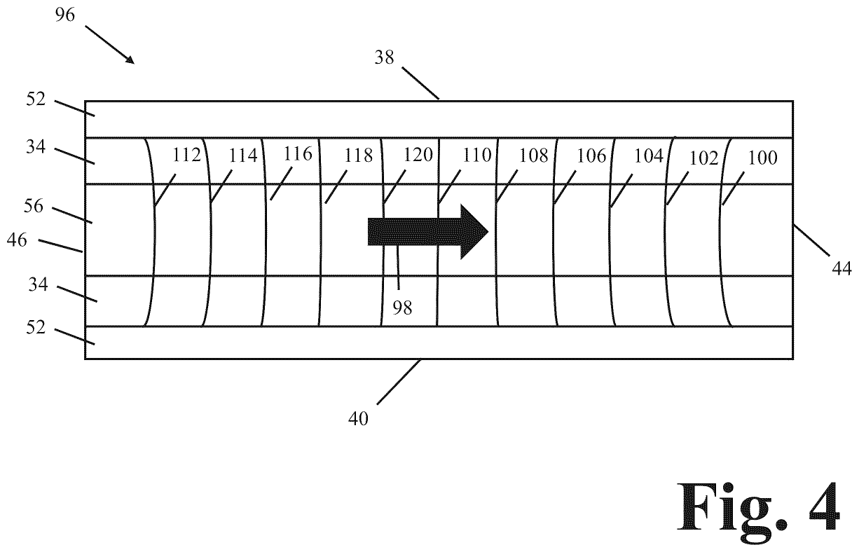

FIG. 4 is a graphical, top view of a third embodiment of a SiMBAL 96 according to the present invention.

The SiMBAL 96 includes a chip 52, a grating structure 34, and an emitter 56. As with the SiMBAL 36, the SiMBAL 78 includes a metal layer (not shown) that is co-extensive with the footprint of the emitter 56.

The SiMBAL 96 also has a first side 38 and a second side 40. As with the prior embodiments, the SiMBAL 96 includes a first end 44 and a second end 46. The first end 44 is the partially reflective (PR) end. And, like the SiMBALs 36, 78, the second end 46 is the highly reflective (HR) end.

When the emitter 56 is energized, the emitter 56 generates laser light 98 that travels in the direction of the arrow 98 to exit from the emitter 56 through the first end 44.

The SiMBAL 96 also includes a plurality of grooves, labeled as a first groove 100, a second groove 102, a third groove 104, a fourth groove 106, a fifth groove 108, a sixth groove 110, a seventh groove 112, an eighth groove 114, a ninth groove 116, a tenth groove 118, and an eleventh groove 120. As with the embodiments illustrated in FIGS. 2 and 3, the grooves 100, 102, 104, 106, 108, 110, 112, 114, 116, 118, 120 are representative of a much larger, actual number of grooves included in the grating structure 34.

As should be apparent from FIG. 4, the SiMBAL 96 combines the grating structure 34 from the SiMBAL 36 with the grating structure 34 from the SiMBAL 78. In particular, the grooves 100-108 have progressively larger radii of curvature as established from the first end 44 toward the second end 36. The grooves 112-120 have progressively increasing radii of curvature as established from the second end 46 to the first end 44. The groove 110 is contemplated to have an infinite curvature.

In this embodiment, the first group of grooves 100-108 face toward the first end 44, similar to the construction illustrated in FIG. 3. The second group of grooves 112-120 face toward the second end 46 of the emitter 56. As such, some of the grooves face in one direction while others of the grooves face the opposite direction.

FIG. 5 illustrates a fourth embodiment of a SiMBAL 114 according to the present invention.

The SiMBAL 114 shares many of the same features of the other embodiments of the SiMBAL 36, 78. To facilitate the discussion of the SiMBAL 114, the same reference numbers are used to refer to the same and/or similar structures described in connection with the SiMBAL 36, 78.

SiMBAL 114 includes a chip 52, a grating structure 116, and an emitter 56. As with the SiMBAL 36, 78, the SiMBAL 114 includes a metal layer (not shown) that is co-extensive with the footprint of the emitter 56.

The SiMBAL 114 has a first side 38 and a second side 40. As with the prior embodiment, the SiMBAL 114 has a first end 44 and a second end 46. The first end 44 is the partially reflective (PR) end. And, like the SiMBAL 36, 78, the second end 46 is the highly reflective (HR) end.

When the emitter 56 is energized, the emitter 56 generates laser light 118 that travels in the direction of the arrow 118 to exit from the emitter 56 through the first end 44.

As should be apparent from FIG. 5, the grating structure 116 in the SiMBAL 114 does not extend the entire length of the emitter 56, as in the prior embodiments. Instead, the grating structure length 120 is less than both the chip length 42 and the emitter length 60.

In this embodiment, the grating structure 116 also includes a plurality of grooves that are labeled as a first groove 122, a second groove 124, a third groove 126, a fourth groove 128, a fifth groove 130, and a sixth grove 132. The grooves 122, 124, 126, 128, 130, 132 are arranged with increasing radii of curvature from the first end 44 of the SiMBAL 114 to the second end 46 of the SiMBAL 14.

The arrangement of grooves in the SiMBAL 114 follows the same orientation as the arrangement of the grooves for the SiMBAL 36 illustrated in FIG. 2.

As should be apparent from the foregoing, the grating structure 116 alternatively may incorporate the orientations of the grooves from the SiMBAL 78 or the SiMBAL 96 without departing from the scope of the present invention.

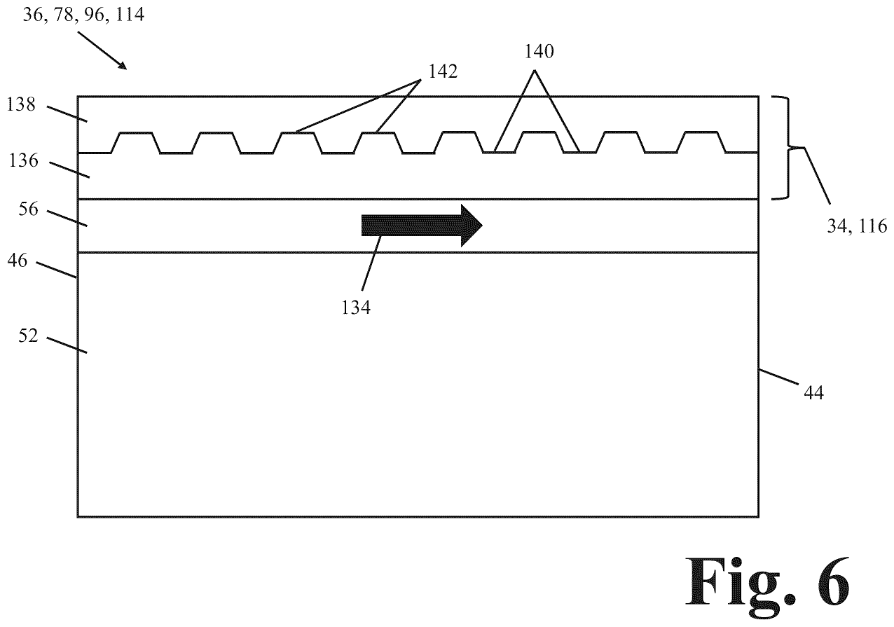

FIG. 6 is a cross-sectional side view of a first embodiment of the grating structure 34, 116 according to the present invention. The cross-section is taken along a least a portion of the SiMBALs 36, 78, 96, 114 described in connection with FIGS. 2-5. More specifically, the cross-section of FIG. 6 is taken along a centerline of the chip 52 at a point that includes at least a portion of the grating structure 34, 116.

As illustrated, the SiMBALs 36, 78, 96, 114 include the chip 52 with the emitter 56 being disposed atop the chip 52. The SiMBALs 36, 78, 96, 114 include a first end 44 and a second end 46. As discussed hereinabove, the first end 44 is the partially reflective (PR) end, while the second end is the highly reflective (HR) end.

As in the described embodiments of the SiMBALs 36, 78, 96, 114, the laser light 134 is created within the emitter 56 and exits from the SiMBALs 36, 78, 96, 114 through the first end 44. This is indicated by the arrow 134.

In the embodiment illustrated in FIG. 6, the grating structure 34, 116 has two parts, semiconductor layer 136 and a metal layer 138. The interface between the semiconductor layer 136 and the metal layer 138 form peaks 142 and valleys 140. The valleys 140 and the peaks 142 establish the shape and contour of the diffraction grating that forms the grating structure 34, 116. The grooves 140 and/or valleys 142 correspond to and/or define the plurality of grooves discussed hereinabove.

In FIG. 6, the valleys 140 and the peaks 142 are illustrated as being trapezoidal in shape. This illustration is merely exemplary. The peaks 142 and the valleys 140 may have any shape without departing from the scope of the present invention. Representative shapes include, but are not limited to circular, sinusoidal, square, triangular, trapezoidal, etc.

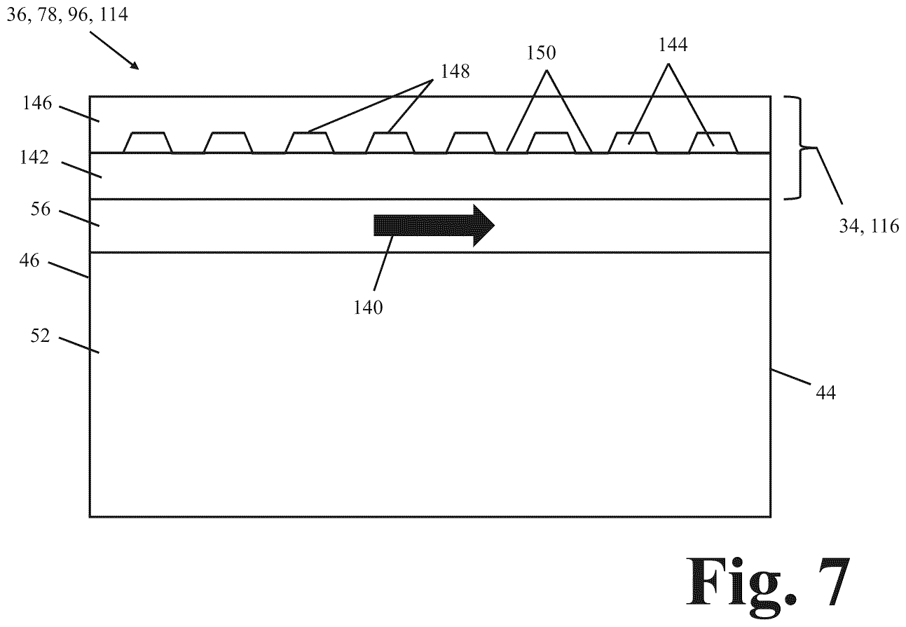

FIG. 7 is a cross-sectional illustration of a second embodiment of the grating structure 34, 116 of the present invention. As with FIG. 6, the cross-section is taken along a least a portion of the SiMBALs 36, 78, 96, 114 described in connection with FIGS. 2-5. As with FIG. 6, the cross-section of FIG. 7 is taken along a centerline of the chip 52 at a point that includes at least a portion of the grating structure 34, 116.

As in FIG. 6, the SiMBALs 36, 78, 96, 114 include the chip 52 with the emitter 56 being disposed atop the chip 52. The SiMBALs 36, 78, 96, 114 include a first end 44 and a second end 46. As discussed hereinabove, the first end 44 is the partially reflective (PR) end, while the second end is the highly reflective (HR) end.

As in the described embodiments of the SiMBALs 36, 78, 96, 114, the laser light 140 is created within the emitter 56 and exits from the SiMBALs 36, 78, 96, 114 through the first end 44. This is indicated by the arrow 140.

In the embodiment illustrated in FIG. 7, the grating structure 34, 116 has three parts, a semiconductor layer 142, a dielectric layer 144, and a metal layer 146. Here, the dielectric layer 14 cooperates with the metal layer 146 to form the peaks 148 and define the valleys 150 between the peaks 148. As should be apparent, the dielectric layer fills the peaks 148. As such, the dielectric layer 144 is discontinuous in this embodiment.

As with the embodiment illustrated in FIG. 6, the valleys 150 and the peaks 148 are illustrated as being trapezoidal in shape. Again, this illustration is merely exemplary and not limiting of the present invention. The peaks 148 and the valleys 150 may have any shape without departing from the scope of the present invention. Representative shapes include, but are not limited to circular, sinusoidal, square, triangular, trapezoidal, etc.

FIG. 8 is a cross-sectional illustration of a third embodiment of the grating structure 34, 116 in accordance with the present invention. As with FIGS. 6 and 7, the cross-section is taken along a least a portion of the SiMBALs 36, 78, 96, 114 described in connection with FIGS. 2-5. As with FIGS. 6 and 7, the cross-section of FIG. 8 is taken along a centerline of the chip 52 at a point that includes at least a portion of the grating structure 34, 116.

As in FIGS. 6 and 7, the SiMBALs 36, 78, 96, 114 include the chip 52 with the emitter 56 being disposed atop the chip 52. The SiMBALs 36, 78, 96, 114 include a first end 44 and a second end 46. As discussed hereinabove, the first end 44 is the partially reflective (PR) end, while the second end is the highly reflective (HR) end.

As in the described embodiments of the SiMBALs 36, 78, 96, 114, the laser light 152 is created within the emitter 56 and exits from the SiMBALs 36, 78, 96, 114 through the first end 44. This is indicated by the arrow 152.

In the embodiment illustrated in FIG. 7, the grating structure 34, 116 has three parts, a semiconductor layer 142, a dielectric layer 144, and a metal layer 146. Here, the dielectric layer 14 fills the valleys 154 between the peaks 156. In this embodiment, the peaks 156 are formed by the semiconductor layer 142.

As in FIGS. 6 and 7, the valleys 154 and the peaks 156 are illustrated as being trapezoidal in shape. As before, this illustration is merely exemplary of the many shapes that are contemplated for the present invention. The peaks 156 and the valleys 154 may have any shape without departing from the scope of the present invention. Representative shapes include, but are not limited to circular, sinusoidal, square, triangular, trapezoidal, etc.

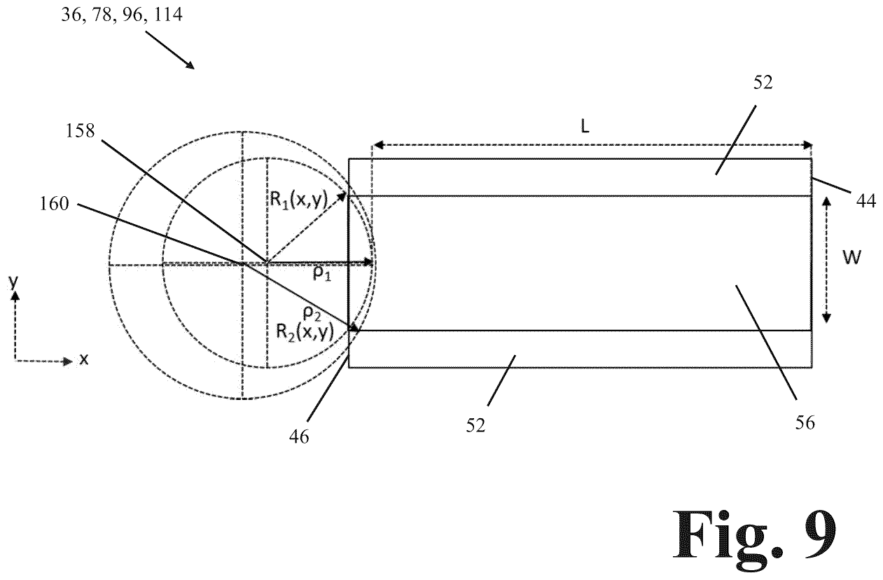

FIGS. 9-11 are provided to provide a non-limiting explanation of some of the mathematical concepts underlying the construction of the SiMBALs 36, 78, 96, 114. In particular, FIGS. 9-11 are provided to assist with an understanding of how the grating structure 34, 116 is designed and constructed. The examples discussed in connection with FIGS. 8-10 are not intended to be limiting of the present invention. Instead, they illustrate the wide breadth and scope of the present invention.

FIG. 9 is a top view of a SiMBAL 36, 78, 96, 114 according to the present invention.

FIG. 9 assists with a discussion of the parameters employed to define the grooves in the grating structures 34, 116.

For at least one aspect of the present invention, the curvature of the grooves is designed so that, in a cold cavity configuration, i.e., under very low heat load, the radius of curvature of the grating at the stripe edge (the first end 44) is given by ρ₁ and the radius of curvature at the other end (the second end 46) is given by ρ₂. The radius of curvature satisfies the condition 1/ρ₂=0. In other words, the grating line is parallel to the facet at one end, and it has a radius of curvature of ρ₂. The radius of curvature of grating lines in between gradually vary to conform to the stated conditions.

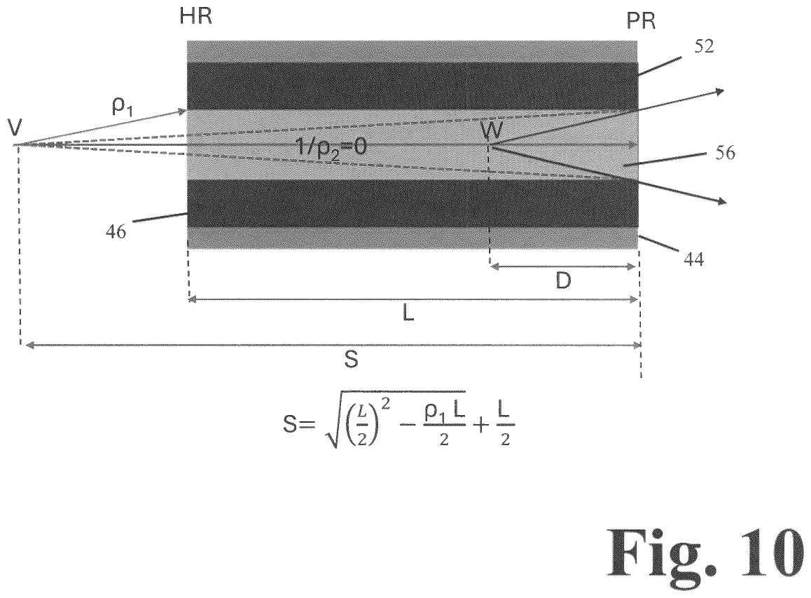

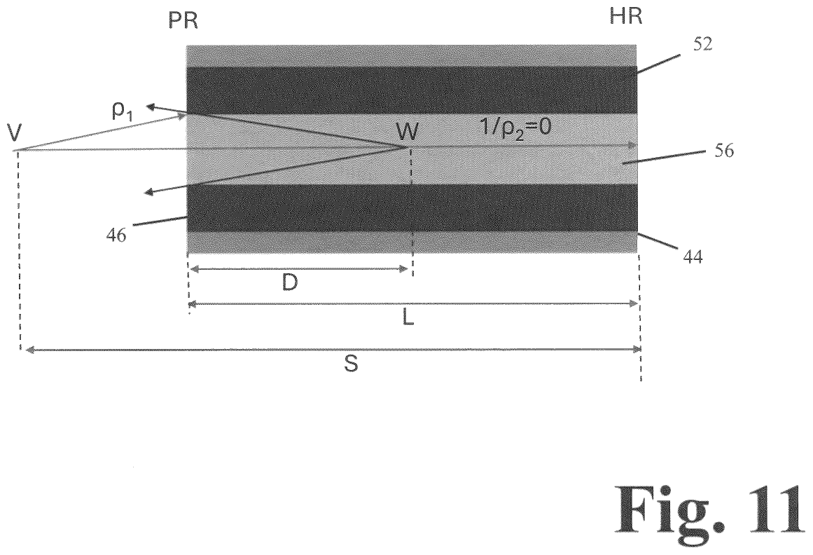

Along the center line of the stripe, the grating pitch, Λ, satisfies the condition,

$$Λ = m \times λ / {n}_{eff} ,$$

where m is the order of grating and λ is the vacuum wavelength and n_{eff} is the effective index of the lasing mode. In this configuration, the wave propagating in the laser appears to emanate from a virtual point, V, located outside the laser diode chip, as shown in FIGS. 10 and 11. From this focal point, curved wave fronts propagate towards the output mirror at the first end 44. After each round trip, the radius of curvature of these wave fronts is reproduced. However, due to the refraction at the output facet, the origin of the wave fronts seems to be at a focal point inside the laser diode chip, which is called the virtual waist, W. This point is located at a distance of D=S/n_{eff} behind the output facet where n_{eff} is the effective index of lasing mode.

Since the origin of the horizontal and vertical far fields are separated by the distance D, this type of semiconductor unstable resonator laser exhibits an astigmatism having a value of D. A magnified image of the virtual source can be measured in the plane of the corrected far field.

With continued reference to FIG. 9, the radius of curvature of the p^{th} grating line for an m^{th}-order grating is defined as:

$${R}_{p} ( x , 0 ) = ( {ρ}_{1} + ( m p λ {n}_{eff} ) and ( {ρ}_{1} + ( m p λ {n}_{eff} ) ) = \sqrt{{ax}^{2} + b {y}^{2}}$$

Where “a” and “b” are arbitrary constants that define the ellipticity of the curves.

For example, at y=0, R₁=ρ₁, when a=b=1.

$$At x = {ρ}_{2} {R ( x , y )}^{- 1} = 1 / \sqrt{{x}^{2} + {y}^{2}} = 0 , 1 / R ( x , 0 ) = 1 / ( {ρ}_{2} ) = 0 .$$

The radius of curvature of the 2nd grating line is then given by:

$${R}_{2} ( x , 0 ) = ( {ρ}_{1} + ( m p λ {n}_{eff} ) = {ρ}_{2} .$$

So when using 1^{st} order grating, i.e., m=1 and p=1 and a=1 and b=1,

$${ρ}_{2} = ( {ρ}_{1} + ( λ {n}_{eff} ) = \sqrt{{x}^{2} + {y}^{2}}$$

But in general, ρₚ=(ρ₁+(mpλn_{eff}))=\sqrt{ax²+by²}.

The round trip magnification factor is defined by: M=(ρ₁+L)/(ρ₁−L).

A large magnification factor will lead to smaller virtual source. Hence, a brighter source but also incur higher round trip losses due to more divergent path inside the cavity. This tends to limit the slope efficiency. A smaller magnification factor leads to lower losses but will be limited in its ability to suppress higher order modes. Typically, 3>M>1 is desirable and the exact magnification factor depends on the length and the width of the laser diode.

With continued reference to FIG. 9, it is noted that adjacent ones of the plurality of grooves not only have different radii of curvature, the grooves have different focal points 158, 160. In this case, the focal points 158, 160 are adjacent to the second end 46 of the SiMBAL 36, 78, 96, 114. This is consistent with the embodiment of the SiMBAL 78 illustrated in FIG. 3, for example.

With reference to FIG. 10, it is noted that the SiMBAL shows a curved grating with a radius of curvature of grating line located at curved end by ρ₁ and by ρ₂ at the opposite end and it satisfies the radius of curvature condition 1/ρ₂=0. This device has a cavity length of L with a virtual source located at a distance D from the opposite facet to the curved grating. The HR is located at curved grating side of the facet.

With respect to FIG. 11, this cross-sectional side view of the SiMBAL shows a curved grating with a radius of curvature of grating line located at curved end by ρ₁ and by ρ₂ at the opposite end and it satisfies the radius of curvature condition 1/ρ₂=0. Device has a cavity length of L with a virtual source located at a distance D from the front facet with the curved grating.

As discussed hereinabove, the embodiments of the present invention are exemplary only and are not intended to limit the present invention. Features from one embodiment are interchangeable with other embodiments, as should be apparent to those skilled in the art. As such, variations and equivalents of the embodiments described herein are intended to fall within the scope of the claims appended hereto.

What is claimed is:

1. An edge-emitting semiconductor broad area laser, comprising:
a chip;
an emitter disposed on the chip;
a grating structure disposed on the emitter; and
a metal layer disposed on the grating structure;
wherein, when operational, the emitter emits laser light from the first end thereof; and
wherein the grating structure comprises a plurality of grooves that exhibit progressively larger radii of curvature between the first end and the second end.

2. The edge-emitting semiconductor broad area laser according to claim 1, wherein
the first end comprises a partially reflective surface; and
the second end comprises a highly reflective surface.

3. The edge-emitting semiconductor broad area laser according to claim 1, wherein
the first end comprises a highly reflective surface; and
the second end comprises a partially reflective surface.

4. The edge-emitting semiconductor broad area laser according to claim 1, wherein:
the chip includes a first end, a second end, a first side, and a second side,
the chip defines a chip length between the first end and the second end,
the chip defines a chip width between the first side and the second side,
the grating structure defines a grating structure length between the first end and the second end,
the grating structure defines a grating width between the first side and the second side, and
the grating structure width is less than or equal to the chip width.

5. The edge-emitting semiconductor broad area laser according to claim 4, wherein the grating width is less than the chip width.

6. The edge-emitting semiconductor broad area laser according to claim 4, wherein:
the emitter defines an emitter length between the first end and the second end,
the emitter defines an emitter width between the first side and the second side, and
the emitter width is less than or equal to the grating structure width.

7. The edge-emitting semiconductor broad area laser according to claim 6, wherein the emitter width is less than the grating structure width.

8. The edge-emitting semiconductor broad area laser according to claim 1, wherein the grating structure comprises:
a semiconductor layer; and
the metal layer,
wherein the interface between the semiconductor layer and the metal layer define peaks and valleys that establish the plurality of grooves.

9. The edge-emitting semiconductor broad area laser according to claim 1, wherein the grating structure comprises:
a semiconductor layer;
a dielectric layer; and
the metal layer,
wherein the dielectric layer defines peaks that establish the plurality of grooves.

10. The edge-emitting semiconductor broad area laser according to claim 1, wherein the grating structure comprises:
a semiconductor layer;
a dielectric layer; and
the metal layer,
wherein the semiconductor layer defines peaks that establish the plurality of grooves and the dielectric layer fills the valleys.
